(19) United States
(12) Patent Application Publication
(10) Pub. No.: US 2009/0020415 A1
(43) Pub. Date: Jan. 22, 2009

(54) "Iontron" ion beam deposition source and a method for sputter deposition of different layers using this source

(76) Inventors: Michael Gutkin, Calabasas, CA (US); Alexander Bizyukov, Kharkiv (UA); Vladimir Sleptsov, Moscow (RU); Ivan Bizyukov, Kharkiv (UA); Konstantin Sereda, Kharkiv (UA)

Correspondence Address: Michael Gutkin, 5033 Dantes View Drive, Calabasas, CA, 91301, US

(21) Appl. No.: 11/879,136

(22) Filed: Jul. 16, 2007

(51) Int. Cl. C23C 14/46

(52) U.S. Cl. 204/192.11; 204/298.04

(57) ABSTRACT

The present invention discloses technology for thin film ion beam sputter deposition on a substrate. The apparatus is a self-contained ion beam deposition source, which can be attached to or positioned inside of a vacuum chamber where substrates are located. This source consists of one or more ion beam sources combined with one or more sputtering targets and a unified magnetic field acting as a devise controlling delivery of the charged particles to the treated by the Iontron workpiece (substrate). The ion beam emits ion beams toward the target that generate sputtered particles directed toward the substrate, thus creating a thin film on the surface of the substrate. The target can be electrically biased, not biased or floating, thus allowing for modulation of the location upon which the charged ions impinge the target. Additionally, the position of the target can be adjusted relatively to the ion beam.

### FIELD OF THE INVENTION

This invention describes a system and methods for performing ion beam sputter deposition, particularly an ion beam sputtering source which combines an ion beam source, and a sputtering target. The sputtering target can be electrically biased and its position can change relative to the ion source. In addition the invention includes a magnetic system to control the flux of charged particles directed outside of the source.

The invention also describes a method for ion beam sputter deposition of metals, dielectrics and semiconductors.

### BACKGROUND OF THE INVENTION

Thin films are used in many diverse applications. Some applications include, for example, data storage applications, magnetic disk memories, magnetic tape storage systems, optical films, semiconductors devise manufacturing, protective coatings and many others. The films can include a single layer or multiple layers.

A number of processing techniques are currently used to form thin films, including Molecular Beam Epitaxy (MBE), thermal evaporation, electron beam evaporation, deposition by the different types of magnetrons including so-called planar magnetron, S-gun and others and Ion Beam Deposition (IBD).

MBE is useful for depositing layers at very low energy, which can produce pseudo epitaxial layers, physical vapor deposition (PVD) is useful for depositing layers at a higher energies. Ion beam sputter deposition (IBSD) is useful for depositing layers at even higher energies than PVD and reduced pressures, which can produce layers with higher crystallinity as well as fewer defects and which are substantially smoother.

Thin film deposition techniques using ion beam sputtering is well established. In the typical process, an ion beam of relatively heavy ions is directed at a target to cause ejection of atomic particles. These particles are collected on a substrate to form a film. In some variations of the technique, two ion beam sources are used, usually a sputtering beam is directed at a target and the second beam is directed at the depositing film. For a general description of these techniques see Chapman, Glow Discharge Processes 1980—published by John Wiley & Sons, Inc. pp 262-270, 272-276.

The performance of the different thin film deposition techniques is described in U.S. Pat. No. 4,142,958 filed on Apr. 13, 1978 as wells as other patents referenced in current application.

Most of these ion beam deposition systems are based on the commercially available Gridded Ion Sources (Kaufman Type). In general, ion beam deposition systems manufactured in industry are very big and complex industrial machines.

Another approach is the utilization of the low energy ion beams with an ion beam energies of about 50 eV or less. The energy, of the ions, required to sputter the target is achieved, not by acceleration of the ion source to a high energy, but by negatively biasing the target relative to the ground (see e.g. U.S. Pat. No. 6,843,891, filed on Jan. 19, 2001)

Yet another approach is a combined ion source and sputtering magnetron (see e.g. U.S. Pat. No. 6,124,183 filed on Jan. 13, 1999)

However, all the above described ion beam deposition systems have shortcomings. For example:

Uniform coatings can be made only on limited surfaces, and then only by keeping the surfaces in constant motion such as in a planetary or in linear motion. (see e.g. U.S. Pat. No. 4,424,103 filed on Apr. 4, 1993).

The ion beam source, target and substrates are located at a considerable distance away from each other, thus making it a necessity to construct a large size dedicated vacuum chamber. Ion beam sputtering systems are limited to low production rates.

The flux of the charged particles and energetic neutrals, arriving on the workpiece (substrate), can not be controlled, which is critical for many applications including, but not limited to thin films components of magnetic sensors, organic light emitting displays, optical coatings and many others.

Scalability for use on large work pieces (substrates) is difficult to achieve.

The target utilization is very limited.

RF or AC based power supply are required to deposit non-conductive or low conductivity materials.

Neutralizers with a separate power supplies, are needed, in order to compensate charge of the substrates, particularly during deposition of the dielectric or low conductivity materials.

The current invention overcomes the limitations of previous ion beam deposition systems and methods.

### SUMMARY OF THE INVENTION

The device of the current application is a sputtering apparatus containing an ion source and a magnetic assembly, wherein the magnetic assembly is configured to be positioned between a target and a substrate, and wherein the target comprises a material which is sputtered onto the substrate. In one embodiment the magnetic assembly generates a magnetic field having a component parallel to the substrate, wherein the magnetic field shields the passage of charged particles onto the substrate.

In one embodiment the magnetic assembly creates a magnetic field having a component perpendicular to the substrate, wherein the magnetic field induces the passage of charged particles to the substrate.

In one embodiment, the magnetic assembly is further positioned between an ion beam generated by the ion source and the substrate.

In one embodiment, the magnetic assembly creates a magnetic field having a component parallel to the substrate, wherein the magnetic field shields the passage of charged particles onto the substrate.

In one embodiment the magnetic assembly creates a magnetic field having a component perpendicular to the substrate, wherein the magnetic field induces the passage of charged particles to the substrate.

In one embodiment, the device of the current application further contains a target assembly wherein the target assembly is configured to contain the target, and wherein the target assembly comprises a mechanical system for positioning the target relative to the ion source.

In one embodiment the device of the current invention further comprising a power supply in electrical communication with the target assembly, wherein the power supply is configured to apply a biasing potential to the target. The application of the biasing potential to the target in the ion beam sputter deposition source of the invention will change the direction of the ion flux impinging on the target thus creating means to increase target utilization. The energy of the ions arriving on the surface of the target are greater than about 100 eV when there is no bias applied to the target. However if a bias is applied to the target, then the resulting electrical field will change the energy of the ions impinging onto the target. Application of the biasing potential can change the direction of the ion flux impinging onto the target, thus changing the profile of the target erosion by the ion beam and thus creating a means to increase target utilization

In one embodiment the target assembly is a rotatable cylinder.

In one embodiment the device of the current application, further comprises a second magnetic assembly positioned between the target and the substrate.

In one embodiment the second magnetic assembly creates a magnetic field parallel to the substrate and wherein the second magnetic field shields the passage of charged particles onto the substrate.

In one embodiment, the second magnetic assembly is further positioned between an ion beam generated by the ion source and the substrate.

In one embodiment of the current invention, a sputtering apparatus containing an ion source, a power supply and a target assembly is disclosed. The power supply is in electrical communication with the target assembly and is configured to apply a biasing potential on a target contained by the targeting assembly, and wherein the target contains a material to be sputtered onto a substrate.

In one embodiment, a method of preventing the passage of charged particles onto a substrate during a sputtering process is disclosed. The method comprises positioning a magnetic assembly between the substrate and a target, wherein the magnetic field assembly generates a magnetic field parallel to the substrate, and wherein the target contains a material to be sputtered onto the substrate.

In one embodiment, the method further comprises positioning the magnetic assembly between the substrate and an ion beam.

In one embodiment, the method further comprises applying a biasing potential to the target, wherein applying the biasing potential to the target changes the direction of the ion beam flux impinging on the target and thus changes the location of erosion of the target by the ion beam.

### BRIEF DESCRIPTION OF THE DRAWINGS

FIG. 1 is a cross-sectional view of an ion beam sputter deposition source of the invention with magnetic field on top of the source to prevent bombardment of substrate by charged particles.

FIG. 2 is a cross-sectional view of an ion beam sputter deposition source of the invention with magnetic field on top of the source promoting ion beam bombardment of the substrate—“Ion assist deposition”

FIGS. 3 and 4 are top down views depicting different shapes of the ion beam sputter deposition source with the ion beam of the ring or elliptical configuration

FIG. 5 is a cross-sectional view of an ion beam sputter deposition source with an additional magnetic focusing of the ion beam for very high target utilization

FIGS. 6 and 7 are samples of different variations of the ion beam deposition source of the invention having one or more sources of the ion beam

FIG. 8 represents the device of the invention with cylindrical rotational target

### DETAILED DESCRIPTION OF THE INVENTION

The ion beam deposition apparatus of the current invention (Iontron) is a unique ion beam deposition source which allows ion beam sputter deposition of the conductive as well as not conductive thin films, while at the same time controlling the amount of the charged particles reaching the work piece (substrate). The apparatus, of the current invention, can be installed in a variety of vacuum systems. The device, of the current invention combines, the dimensional simplicity of the magnetrons and the capability of the ion beam deposition systems. The device, of the current invention, can deposit films on static and dynamic substrates.

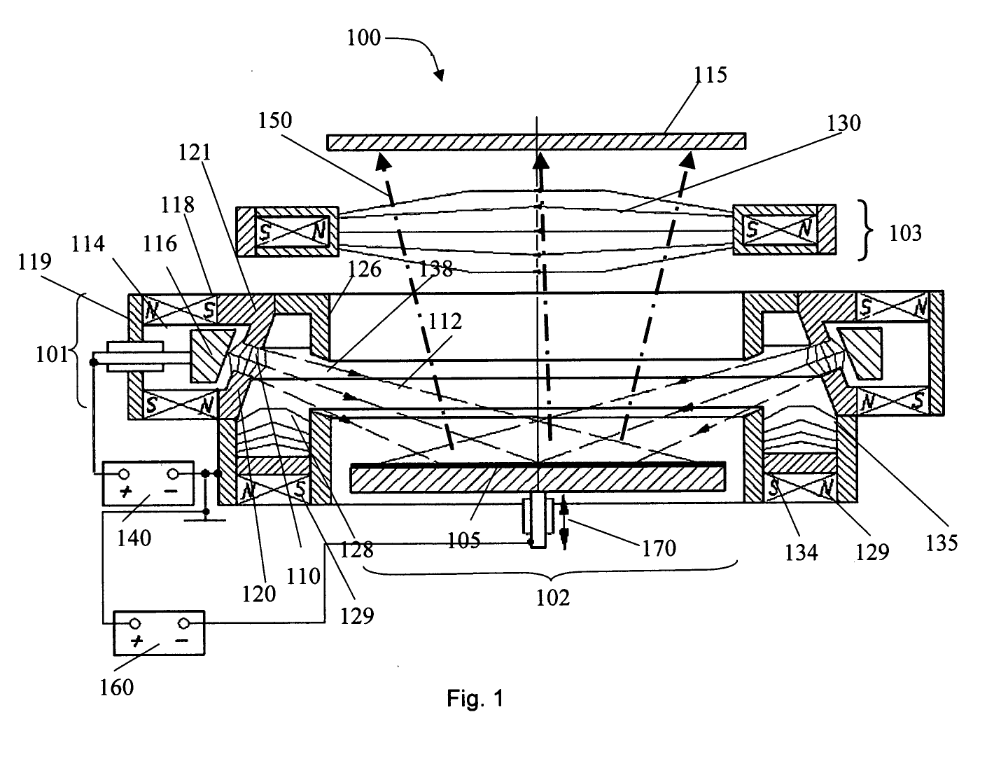

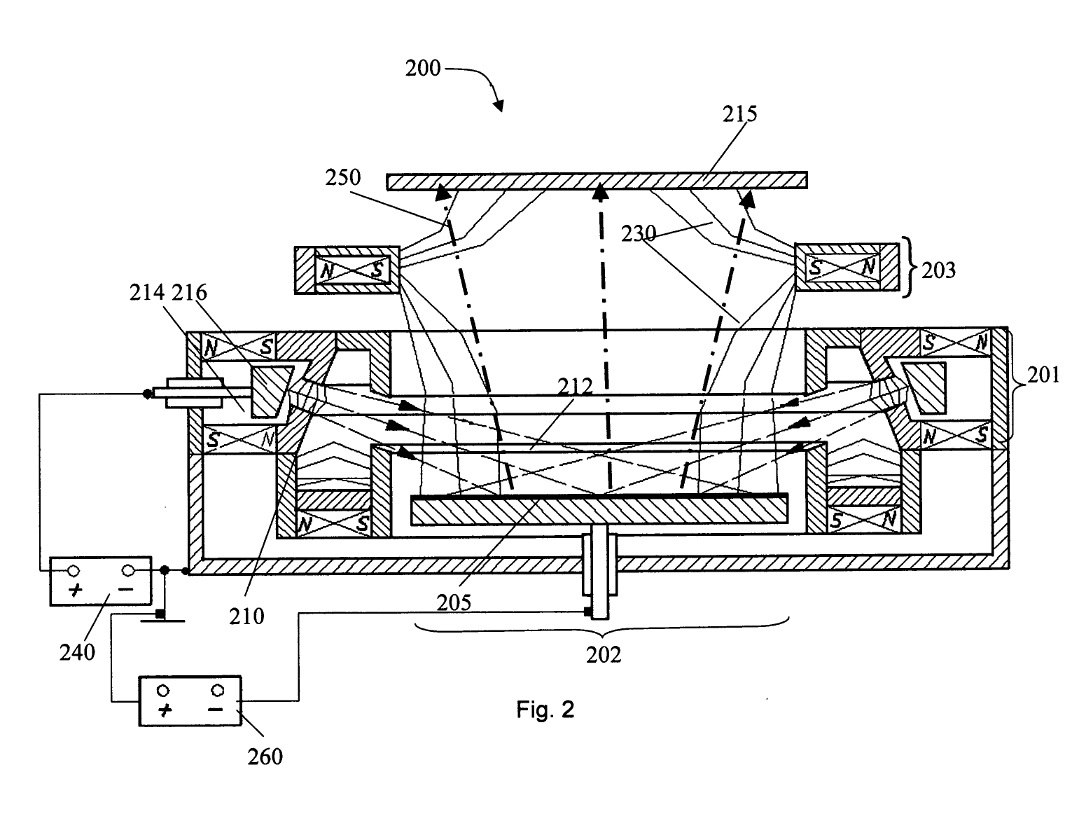

Referring now to the drawings wherein like reference numerals are used throughout the various views to designate like parts. For example feature 101 in FIG. 1 is analogous to feature 201 in FIG. 2.

As shown on the FIG. 1 the ion beam deposition source 100 of the current invention comprises a Focused Anode Layer Ion Source 101 with converging and charge compensated beam. A Focused Anode Layer Ion Source is described in the U.S. patent application Ser. No. 11/704,476 filed on Feb. 9, 2007, which is hereby incorporated by reference as fully put forth below. Briefly, the ion source 101, is an ion source with a closed electron drift containing an azimuthally closed channel (discharge channel) 114 for ionization and acceleration of the operational media, such as an ionizable gas. The channel 114 is formed by the inner walls of the magneto-conductive housing (cathode) 119 and azimuthally-closed anode 116 contained within the magneto-conductive housing 119. Plasma discharge is ignited in the cross-magnetic and electrical fields when voltage is applied between anode 116 and the cathode 119. A power supply 140 used to apply voltage between the cathode and anode. Discharge is ignited and is well sustained at an operational gas pressure in the range of about 1×10⁻⁵-5×10⁻³ Torr and a discharge voltage of greater than about U=500 V on the anode. The space of ionization and acceleration of the ions of the operational gasses is formed during operation of the ion source 101 in the discharge channel 114 at the outer surface of the anode 116.

The magneto conductive housing 119 forms the ion-emitting slit/aperture 110, through which the ion beam 112 is accelerated. The ion source 101 also contains a means for creation of a magnetic field 118 in the azimuthally-closed channel 114 of the magneto-conductive housing 121. The magneto conductive housing 119 is at ground potential. The emitted ion beam is directed onto target 105.

In order to direct the beam 112 onto target 105, the magnetic poles 120 and 121 and the ion-emitting slit/aperture 110 are tilted at angle in the range of about 10°-75° relative to the plain of the target.

The angle can be optimized within this range in order to, in combination with the position of the target, reduce bombardment of substrate by energetic charged particles that where elastically reflected from the surface of the target (not low energy ions extracted from the plasma above the target) as well as by high-energy atoms. This ballistic type of focusing, in the case of a ring shaped ion source, forms an ion beam 112 having an emission surface unwrapped on a contour and provides a ion beam 112 having a ring shaped crossover area on the target 105.

To overcome the problem associated with charging target surface due to incomplete neutralization of the ion beam 112, the ion beam 112 may be passed through a hollow cathode 126 comprising a metallic azimuthally enclosed cavity 128 with an aperture 138 for the exit of the ion beam.

The hollow cathode 126 works by enabling a small fraction of the ions from the ion beam 112 to collide with the atoms of a neutral gas present in the hollow cathode 126. These collisions ionize the atoms of the neutral gas leading to the generation of primary electrons inside the hollow cathode 126 and the generation of primary plasma. As a result, a self-sustaining gas discharge is formed inside of the hollow cathode during treatment of the dielectric and electrically isolated articles, resulting in charge compensation of the ion beam. The gas discharge is self-sustaining because an additional power supply is not required to induce the formation of the gas discharge in the hollow cathode. The potential difference between the hollow cathode and the substrate enables the formation of the gas discharge. The hollow cathode 126 is supplied with its own magnetic system consisting of the magnets 129 and magnetic pole pieces 134. This configuration establishes a magnetic field of an arch configuration 135 with maximum strength in the range of about 300-1000 Oersted on the internal surface of a cavity of the hollow cathode 126. The presence of the magnetic systems enables enhanced retention of electrons and ions, thus increasing the density of the discharge in the hollow cathode 126 and the efficiency of neutralization of the potential formed on the surface of the substrate. In addition, the outer surface of the hollow cathode 126 protects (shields) the ion-emitting slit/aperture 110 from being hit by the material sputtered from the target 105.

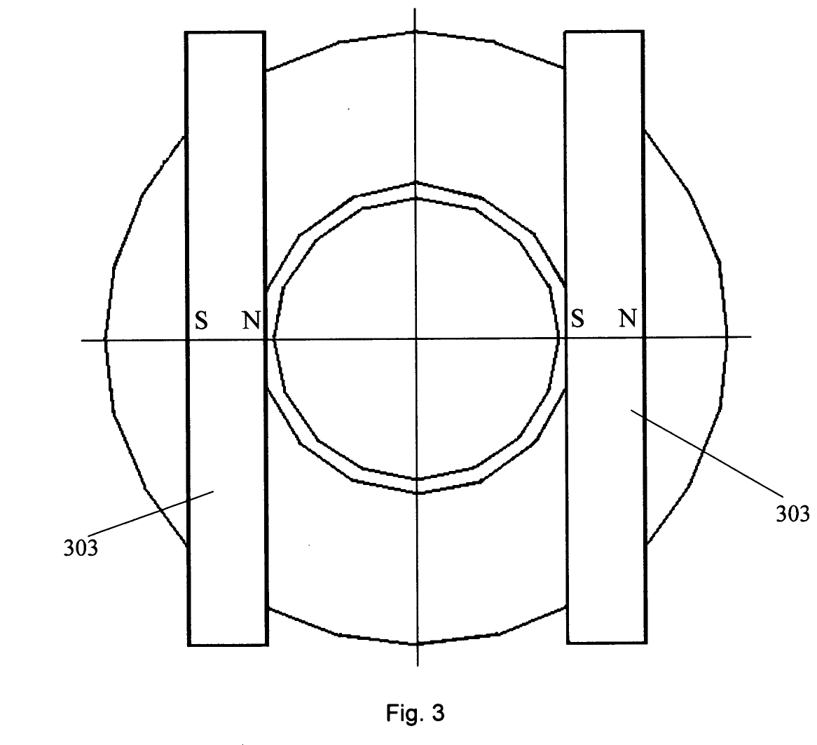

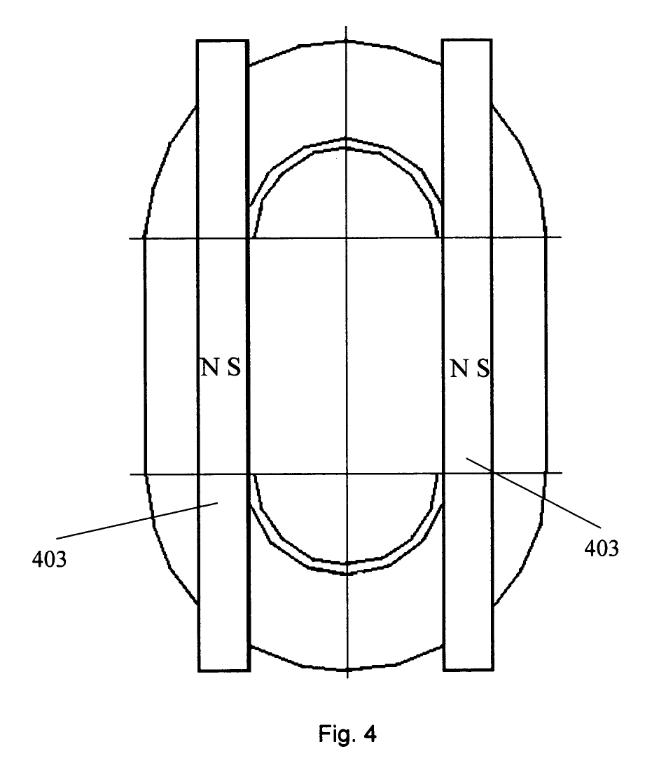

In FIG. 1 the depicted ion beam source 101 has a ring or the elliptical shape. It is well within the scope of this invention that the ion beam has alternative shapes as depicted in FIGS. 3 and 4. Additionally, multiple ion sources may be present in the ion beam sputter deposition apparatus of the current invention.

The ion beam deposition source further comprises a target assembly 102. The target assembly 102 allows the target 105 to change position relative to the one or more ion sources as depicted by arrows 170 The target 105 can be connected to an additional power source 160 that allows the target 105 to be electrically biased relative to the ground or to be isolated from the ground potential. The ion beam deposition source further comprises a magnetic field assembly 103 positioned between target 105 and a work piece (substrate) 115. The purpose of the magnetic field is to control the flux of charged particles. As it is known to those skilled in art, sputter deposition processes take place inside a vacuum chamber where the deposition sources as well as work pieces are placed. The ion beam deposition source 101 of the current invention is mounted inside the vacuum chamber that is evacuated by means of a vacuum pump to a pressure of about 10⁻⁵ Torr or lower. After the low pressure has been achieved an operational media, usually ionizable gas, is introduced into the volume of the vacuum chamber. The ion source 101, directed towards target 105, generates an ion flux (beam) 112 in which the ions have energies greater then about 100 eV. Sputtered particles 150 are ejected from the target 105 by the impinging ions and are deposited on substrate 115.

The magnetic field 130 generated by the magnetic field assembly 103 creates a magnetic field that is designed to control the flux of charged particles toward the substrate.

In one embodiments of the invention magnetic lines of this field do not cross surface of the target 105. This magnetic field 130 has a component directed parallel to the surface of the target with the mean value of the magnetic field H̅ determined by the formula

$$\overline{H} = \frac{1}{L} {\int }_{0}^{L} H ( x ) d x > \frac{{m}_{e} c}{e} \frac{1}{L} \sqrt{\frac{2 ( {ɛ}_{e} + eV )}{{m}_{e}}} ,$$

where L-distance between a target and a substrate, H (x)-distribution of a magnetic field in area from a target up to a substrate in a direction perpendicular to the target surfaces, m_{∈} is the electron mass, c is speed of light, ∈ₑ is energy-secondary emission electrons, V is the potential difference between substrate and the target. The purpose of this field is to reduce the number of defects in a film by reducing the number of charged particles impinging on a substrate.

Secondary electrons emitted from the target by the ion beam and low energy ions created in the space between the ion source and target as the result of the charge exchange between the ions from the ion beam and atoms of the operational gas can be sources of defects in a deposited film. If these charged particles such as secondary electrons and low energy ions impinge on the substrate (work piece) then they can create defects in the deposited on the substrate film.

These secondary electrons and low energy ions form a secondary plasma in a space between target and substrate. The secondary plasma defuses toward surrounding surfaces including surface of the substrate in an ambipolar mode.

Ambipolar diffusion is diffusion of positive and negative particles, in a plasma, at the same rate due to their interaction to the electric field. In general, the forces acting on the ions are different from those acting on the electrons, thus one would expect one species to be transported faster than the other, whether by diffusion or convection or some other process. If such differential transport has a divergence, then it will result in a change of the charge density, which will in return create an electric field that will alter the transport of one or both species in such a way that they become equal.

As the electrons leave the initial volume, they will leave behind a positive charge density of ions, which will result in an outwardly-directed electric field. This field will act on the electrons to slow them down and on the ions to speed them up. The net result is that both ions and electrons stream outward at the velocity much larger than the ion thermal speed but much smaller than the electron thermal speed.

When the magnetic field resulting from the magnetic assembly 103 is present between target and a substrate then the secondary electrons will become “magnetized” and their propagation toward substrate will be limited by the Larmor force. The secondary electrons will move along the magnetic lines toward surfaces (walls, other boundaries) and will be adsorbed. Thus, “a magnetic barrier”, is formed, which protects the surface of a substrate. During ambipolar diffusion the secondary electrons quickly leaving their initial volume, thus creating an ambipolar electrical field. As the ambipolar electric field is generated it forces the ions to move in the same direction as the electrons, toward the surfaces. The movement of the low energy ions create a magnetic field that is crossed by the magnetic field generated by the magnetic assembly 103, thus preventing the low energy ion from moving towards the substrate.

In an alternatively embodiment, as depicted in FIG. 2, the magnetic field assembly could be used to promote bombardment of the substrate by charged particles such as secondary electrons and low energy ions. FIG. 2 represents ion beam sputter deposition source 200 in which magnetic field assembly 203 is designed to promote a bombardment of the surface of the substrate 215 by the charged particles. In this embodiment, the magnetic field lines 230 generated by the magnetic field assembly 203 do not block the charged particles from impinging onto the substrate. Bombardment of the surface, of the substrate, by charged particles may be used, for example, to promote chemical reactions on the surface. In this embodiment the magnetic field between the substrate and the target crosses the target surface and has a component that is perpendicular to the surface of both the target 205 and substrate 215.

In this configuration, of the ion beam sputter deposition source 200 of the current invention creates electrons with secondary emission that will move from the target 205 to the substrate 215. The ions present in the secondary emission will follow them in the same direction.

In addition surface activation by energetic ions, in the apparatus of the current invention, can be achieved by applying a potential to the target 205. The potential can be applied by a power source, for example power source 260. The target potential controls the energy of the electrons present in the space between the target and the substrate. These electrons will additionally ionize the operational gas and induce an electrical potential on the surface of the substrate 215. The induced electrical potential is roughly equal to the potential of the target 205. This substrate bias will attract more ions to the surface of the substrate, thus promoting additional bombardment of the surface of the substrate. The effect of the additional ion bombardment of the surface during thin film deposition is known in industry as an ion assisted deposition. Further, the application of the biasing potential to the target can change the direction of the ion flux impinging on the target through a interaction between electrical field of the target 205 and ions having positive potential, thus creating means to increase target utilization by shifting the location on the target 205 upon which the ion beam impinges.

FIG. 3 and FIG. 4 show a top down view of the ion beam sputter deposition source of the invention representing circular FIG. 3 and elliptical configurations FIG. 4 of one of the described variation of the invention and also depicting an embodiment for positioning the magnetic field assembly, 303 and 403, which controls the flux of the charged particles towards the a substrate as described above.

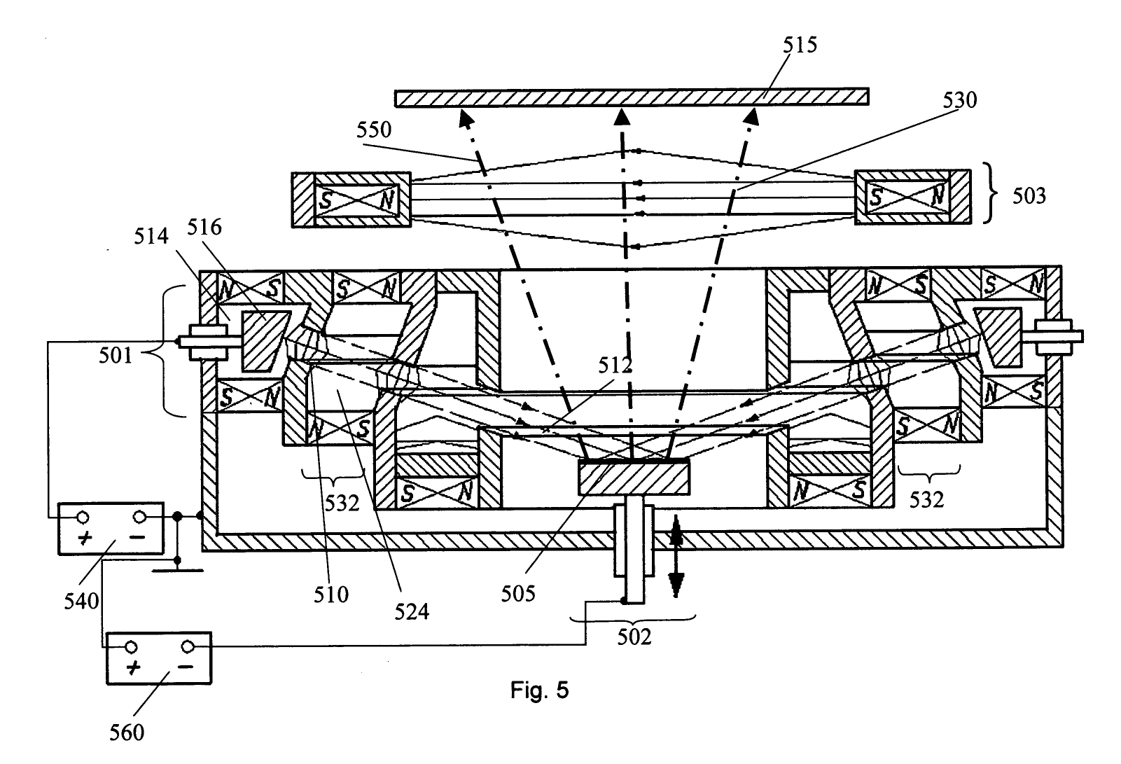

FIG. 5 represents ion beam sputter deposition source of the invention, having a magnetic lens 532 positioned near the slit/aperture 510 of the ion source 501.

Details of the magnetic lens is described in U.S. patent application Ser. No. 11/704,476 filed on Feb. 9, 2007, which is incorporated by reference as noted above. The magnetic lens 532 is used to further focus the ion beam 512. As the ion beam exits the discharge channel 514, have an azimuthally closed anode 516, it passes the pole pieces where electrical field is practically absent, but there is a strong magnetic field B_{⊥} that is perpendicular to the direction of the ion beam flux. Thus, the ion beam experiences Lorenz's forces in the azimuthal direction. These forces increase the ion velocity in the azimuthal direction, and diverges the ion beam in the azimuthal direction. This leads to the defocusing of the beam and decreases the current density of the beam. To compensate for this effect (the azimuthal component of the ion velocity), the beam is directed into the magnetic lens 532 located near the slit/aperture 510 of the ion source 501. The magnetic lens 532 contains a means for establishing a magnetic field 540, 120 and outer 122 magnetic pole pieces, and a slit/aperture 536. The magnetic field of the magnetic lens 532 has a direction opposite to the magnetic vector inside the discharge channel 514 but it is located inside its own azimuthally closed channel 514 that is positioned coaxially relative to the discharge channel. When magnetic fluxes with directions perpendicular to the direction of the ion beam 512 are equal in value then the field established by the magnetic lens 532 together with the magnetic field established in the discharge channel 524 form a “reversive” focusing magnetic system for focusing and compression of the ion beam 512 and provides suppression of the azimuthal divergence of a beam exiting the discharge channel 514, thus increasing the current density of the ion beam 512.

In some applications, when there is a need to use very rare and expensive targets, for example rare isotopes. Introducing the magnetic lens 532 allows for very small targets with diameters ranging from millimeters to a few centimeters.

In one embodiment, the ion source 501 may form an ion beam (s) of conical configuration with apex of a cone with the minimum area on the target.

In one preferred embodiment, the cross-section of the focused ion beam generated by a ring-shaped ion source as a truncated cone shape with diameter of the small basis (the size of the minimal spot on a target) of about twice the thickness of the cross section of the ion beam.

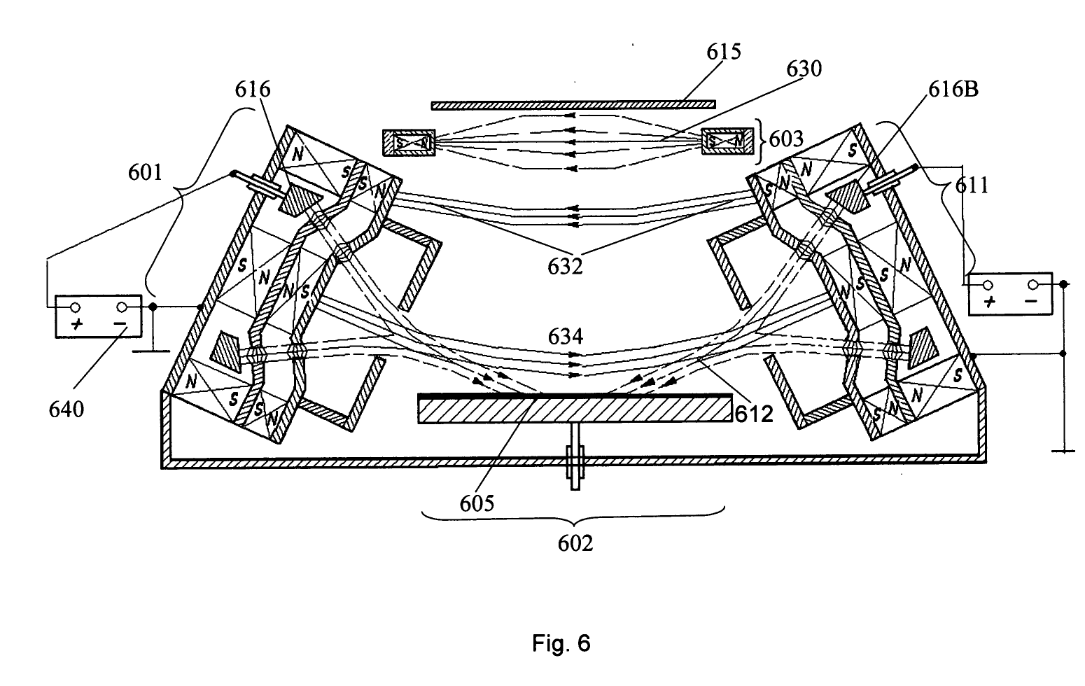

In addition, the focused ion beam from a linear ion beam source 601A, 601B, 701, 801 (FIGS. 6, 7, 8) represents the truncated wedge with a diameter of the small basis (the size of the minimal spot on a target) of about twice the thickness of the cross section of the ion beam

The improvement of the target utilization is achieved by the changing position of the ion beams 612, 712, 812 impinging on the surface of the target 605, 705, 805 by electrical means (changing negative electrical bias applied to the target if target is conductive) via power supply 640, 740, 840 or by mechanical means (change of position of the target relative to the ion beam in case of conductive and non-conductive targets). As a result, maximum target utilization can be achieved while having a minimum spot area of the ion beam on the surface of the target, thus minimizing the area of the ion beam edge non-uniformity.

In systems with ring-shaped ion sources and round or elliptical targets it is nearly impossible to sputter a target close to the center.

Using focusing systems of the reversive type, by introducing a magnetic lens 532, improves focusing, and thus improves target utilization.

The ion beam is directed at the sputtering target 505, which is a part of a target assembly 502. The target assembly may be cooled, using a technology that is well known to those skilled in the art. Target can be supplied with the means to change the electrical potential such as power supply 560. Applying an electrical potential to the target 502 generally applies to the targets made of the conductive materials, although non-conductive targets can be electrically biased by RF Power supplies.

Optimization of the sputtering process for a given material may be achieved by optimizing the acceleration potential of the ion source and/or the electrical potential applied to the target. When using conducting targets the target potential (V) is optimized based on the following relation: eV=∈_{c} cos²α(1−ctgβ·tgα)², where e is the electron charge, X is the energy of ions in a beam, α is an angle of an ion beam relative to a target, β is the angle at which sputtering rate of a target material is maximum.

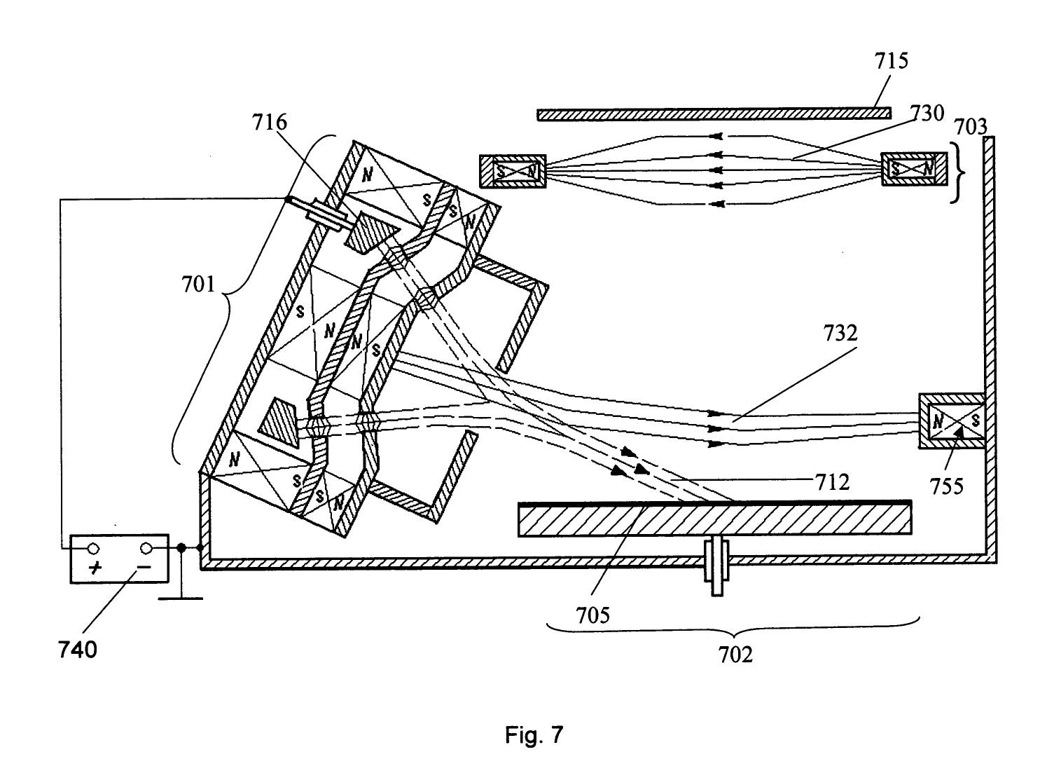

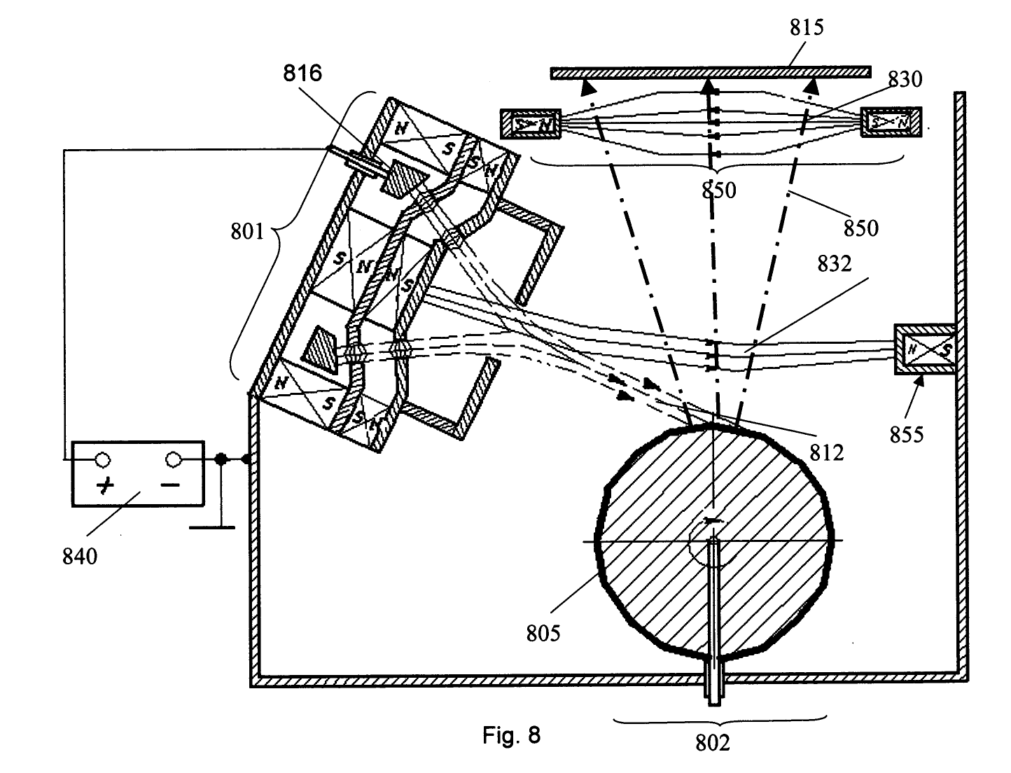

FIGS. 6 and 7 represent other possible configurations of the invention with one and two Focused Anode Layer Ion Sources with converging and charge compensated beam. When two ion sources are used, as depicted in FIG. 6, the configurations of magnetic field employed in each ion source become an important factor of the system. Magnetic fields 632 and 634 emanating from two ion sources 601 and 611 are parallel to the substrate 615 and thus these fields enhancing the effect of the magnetic assembly 603 additionally reducing the number of defects in a film by reducing the number of charged particles impinging on a substrate. The same effect of the enhancement of the magnetic field of magnetic assembly can be achieved when ion beam sputter deposition source of the invention consists of one linear ion source 701 and 801 on FIG. 7 and FIG. 8. In these embodiments of the invention, an additional magnetic field source 755, 855 is added. The additional magnetic field source 755, 855 is located along with the magnetic field of the ion sources 701, 801, respectively and forms magnetic fields 732, 832 with the directions parallel to substrate 715,815, respectively. The additional magnetic field source works as an additional magnetic shield further reducing the number charged particles from impinging onto the surface.

FIG. 8 represent yet another configuration of the invention. This source is equipped with a rotational cylindrical target 805. The Ion flux 812 of the Focused Anode Layer Ion Source with converging and charge compensated beam produces an ion beam flux that has a line in the crossover with the target (i.e. the imprint of the beam on the target is a line). During sputtering from the target 805, the target 805 is eroded by the ion beam along the target line. A cylindrical target 805 rotating during deposition will therefore erode uniformly, thus increasing utilization of the target material even further.

### EXAMPLE 1

An aluminum thin film was deposited by the device of the current invention (Iontron). The target material was Al. The deposition pressure was 5*10⁻⁴ Torr. The operational gas was Ar. The substrate target distance was 180 mm. The deposition rate 350 A/min (˜6 A/sec). Currents of the electrons and ions were measured on the electrically conductive substrate/wafer holder placed instead of a substrate. The diameter of the substrate holder was 150 mm. A cylindrical energy analyzer was used to measure mean energies of the ions and electrons bombarding the substrate/wafer holder which passed through a 15 mm opening in the substrate/wafer holder. Ar ions bombarded the Al target with an average energy of 1000 eV. The ion current was 100 mA. The results are summarized in Table 1.

| | Without | | With | |
|---|---|---|---|---|
| | Magnetic Trap | | Magnetic Trap | |
| | Current | Avg. Energy | Current | Avg Energy |
| Electrons | 4-7 mA | 60 eV | 10-30 μA | 10 eV |
| Ions | 3-5 mA | 300 eV | 30-50 μA | 300 eV |

The above results demonstrate that the presence of a magnetic trap 103, 503, 603, 703, 803 reduces ion and electron current to the substrate by ˜2 orders of magnitude.

Although the invention has been shown in the form of specific embodiments, it is to be understood that the invention is not to be limited to the disclosed embodiments. The embodiments discussed above were given only as examples. Changes and modifications are possible and the invention is intended to cover various modifications and equivalent designs included within the scope of the invention.

What we claim:

1. A sputtering apparatus comprising:
an ion source; and
a magnetic assembly, wherein the magnetic assembly is configured to be positioned between a target and a substrate, wherein the target comprises a material, which is sputtered onto the substrate.

2. The apparatus according to claim 1, wherein the magnetic assembly creates a magnetic field having a component parallel to the substrate, and wherein the magnetic field shields the passage of charged particles onto the substrate.

3. The apparatus according to claim 1 wherein the magnetic assembly creates a magnetic field having a component perpendicular to the substrate, wherein the magnetic field induces the passage of charged particles to the substrate.

4. The apparatus according to claim 1, where the magnetic assembly is further positioned between an ion beam generated by the ion source and the substrate.

5. The apparatus according to claim 4, wherein the magnetic assembly creates a magnetic field having a component parallel to the substrate, wherein the magnetic field shields the passage of charged particles onto the substrate.

6. The apparatus according to claim 4, wherein the magnetic assembly creates a magnetic field having a component perpendicular to the substrate, wherein the magnetic field induces the passage of charged particles to the substrate.

7. The apparatus according to claim 1 further comprising a target assembly wherein the target assembly is configured to contain the target, and wherein the target assembly comprises a mechanical system for positioning the target relative to the ion source.

8. The apparatus according to claim 7, further comprising a power supply in electrical communication with the target assembly, wherein the power supply is configured to apply a biasing potential to the target

9. The apparatus according to claim 8 wherein the target assembly is a rotatable cylinder.

10. The apparatus according to claim 1, further comprising a second magnetic assembly positioned between the target and the substrate.

11. The apparatus according to claim 10, wherein the second magnetic assembly creates a magnetic field parallel to the substrate and wherein the second magnetic field shields the passage of charged particles onto the substrate.

12. The apparatus according to claim 11, wherein the second magnetic assembly is further positioned between an ion beam generated by the ion source and the substrate.

13. A sputtering apparatus comprising:
an ion source, wherein the ion source generates an ion flux;
a power supply; and
a target assembly, wherein the power supply is in electrical communication with the target assembly and is configured to apply a biasing potential to a target contained by the target assembly, wherein the target contains a material to be sputtered onto a substrate, and wherein application of the biasing potential to the target changes the direction of the ion flux impinging on the target.

14. The apparatus according to claim 13 wherein the target assembly is a rotatable cylinder.

15. The device according to claim 13, further comprising a magnetic assembly positioned between the target and the substrate.

16. The device according to claim 15, wherein the magnetic assembly is further positioned between an ion beam generated by the ion source and the substrate.

17. The device according to claim 16, wherein the magnetic assembly generates a magnetic field parallel to the substrate, wherein the magnetic field is configured to shield the passage of charged particles onto the substrate.

18. A method of preventing the passage of charged particles onto a substrate during a sputtering process, the method comprising:
positioning a magnetic assembly between the substrate and a target, wherein the magnetic field assembly generates a magnetic field parallel to the substrate, and wherein the target contains a material to be sputtered onto the substrate.

19. The method according to claim 18, further comprising:
positioning the magnetic assembly between the substrate and an ion beam.

20. The method according to claim 19 further comprising:
applying a biasing potential to the target.
